(19) United States
(12) Patent Application Publication
(10) Pub. No.: US 2008/0197443 A1
(43) Pub. Date: Aug. 21, 2008

(54) Semiconductor Substrate Comprising a Pn-Junction and Method For Producing Said Substrate

(76) Inventors: Franz Schrank, Graz (AT); Rainer Stowasser, Hart bei Graz (AT)

Correspondence Address: COHEN, PONTANI, LIEBERMAN & PAVANE LLP, 551 FIFTH AVENUE, SUITE 1210, NEW YORK, NY, 10176, US

(21) Appl. No.: 11/793,184

(22) PCT Filed: Nov. 9, 2005
(86) PCT No.: PCT/EP05/11992

§ 371 Date: Apr. 7, 2008

(30) Foreign Application Priority Data
Dec. 15, 2004 (DE) 102004060363.4

(51) Int. Cl. H01L 29/36; H01L 21/20

(52) U.S. Cl. 257/506; 438/455; 257/E29.109; 257/E29.024; 257/E21.122

(57) ABSTRACT

An SOI substrate comprising a carrier substrate, a dielectric layer and a semiconductor layer. A continuous pn junction is realized in the semiconductor layer, which pn junction can be produced by applying differently doped partial layers on the SOI substrate. In this way, it is possible to use an SOI substrate for producing semiconductor components and, in particular, rear side diodes.

Substrates comprising SOI semiconductor layers (silicon on isolator) are known in which a monocrystalline semiconductor layer is arranged above a dielectric layer. The dielectric layer is usually the covering layer of a carrier substrate. Known substrates comprising SOI layers are for example semiconductor wafers having a relatively thin monocrystalline layer above an oxide layer. Such substrates comprising SOI layers are known for example with layer thicknesses of approximately 100 Å to 1 μm thickness for semiconductor components and with thicknesses of up to 500 μm for MEMS components (micro electromechanical system). They afford the possibility of leading patternings as far as the dielectric layer and of thus producing for example deeply extending STI isolations (shallow trench isolation) by which adjacent components can be reliably and completely isolated from one another.

With substrates comprising SOI layers it is generally possible to realize thin-film components on mechanically stable carrier substrates. In this way it is possible to produce components having high operating speeds with a low current consumption. Generally, parasitic side effects can be avoided significantly better on substrates comprising SOI layers since it is possible to minimize or eliminate all bulk effects through the buried dielectric layer. MEMS components, too, have already been realized on SOI substrates, in particular inertia sensors having a high seismic mass.

It is known to realize semiconductor components in SOI layers by patterning the surface and in particular by producing doped regions in the surface.

In order to produce substrates comprising SOI layers, it is known, for example, to connect two wafers, at least one of which has an oxide layer on its surface, to one another by means of standard wafer bonding methods. It is also possible to produce the dielectric layer by implanting oxygen into a desired depth of at most approximately 1 μm. In the case of wafer-bonded substrates it is generally necessary to thin the semiconductor layer that is to become the SOI layer to the desired layer thickness after wafer bonding. This can be done by grinding or by breaking off along a buried layer that can be produced prior to bonding by implanting hydrogen into the upper wafer to a given depth of up to approximately 1.5 μm.

U.S. Pat. No. 5,899,712 A discloses a method for producing substrates comprising SOI layers, in which the wafer bonding process is carried out repeatedly, wherein a multilayer construction is obtained having a height that corresponds to the number of wafers bonded one above another times the layer thickness of said wafers. Substrates comprising only one SOI layer in each case are subsequently cut out from said multilayer construction by means of corresponding sawing methods.

It is an object of the present invention to specify a substrate comprising an SOI layer which makes it possible to produce further semiconductor components.

This object is achieved by means of a semiconductor substrate with multilayer construction in accordance with claim 1. Advantageous configurations of the invention and also a method for producing the semiconductor substrate emerge from further claims.

The invention specifies a semiconductor substrate comprising a multilayer construction composed of a carrier substrate, a dielectric layer and a semiconductor layer, a continuous pn junction being formed in the semiconductor layer. The pn junction comprises at least one doped first partial layer and at least one oppositely doped second partial layer. The pn junction is concomitantly produced during substrate production in a manner integrated into the production of the partial layers and is not achieved by subsequent doping of a uniform substrate.

In the semiconductor substrate according to the invention it is possible to realize a semiconductor component, and in particular a semiconductor circuit, which can be realized with a higher layer thickness of a respective partial layer compared with superficially patterned and therefore superficially doped substrates. In particular, a component having a large space charge zone, in particular a diode, can be realized with the semiconductor substrate.

The semiconductor substrate according to the invention comprises at least one monocrystalline SOI layer. It therefore combines the advantages of an SOI substrate with those of a doped conventional wafer. The dielectric layer enables simple patterning as far as the dielectric layer, which in this case can serve as a natural etching stop layer or as some other barrier during patterning.

In one advantageous configuration of the invention, one partial layer of the semiconductor layer is weakly doped in the region of the pn junction. The other partial layer is then preferably highly doped. It is thus possible to enlarge the space charge zone further and to shift it into the region of the weakly doped partial layer. The thickness of this partial layer is then advantageously set such that it is higher than that of the highly doped partial layer. The semiconductor layer can then comprise only these two partial layers.

In a further configuration of the invention, the semiconductor layer comprises a first, relatively thin partial layer having a high doping and of a first conductivity type, above that a second partial layer relatively thicker than said first partial layer and having a weak doping of the first conductivity type, and above that a third partial layer having a weak doping of the second conductivity type. The pn junction is formed between two partial layers each having weak doping and in this case produces a space charge zone extending over relatively large layer thickness regions of the first and second doped layers. By contrast, the first, highly doped, thin partial layer may serve for the connection of a component realized in the semiconductor substrate and can be connected in a simple manner through a trench that is led from the surface of the semiconductor substrate and is subsequently filled with conductive material.

It is also possible to realize a pin structure in the semiconductor layer, that is to say to provide an intrinsic or non-doped partial layer between two doped partial layers.

Preferably, carrier substrate and dielectric layer are realized in the form of a silicon wafer provided with an oxide layer. The oxide layer can be formed in a simple manner by oxidizing the silicon with high dielectric quality and layer uniformity.

In a further configuration of the invention, there is arranged above the semiconductor layer a second dielectric layer and, above the latter, a second monocrystalline semiconductor layer. This yields a substrate having two semiconductor layer planes which are separated by a dielectric layer and in which different components can be realized. It is also possible to realize a vertical integration of identical or interacting different components in this way. Miniaturized components saving semiconductor substrate material and having short wiring paths, therefore short switching times and low ESR values, are obtained as a result.

In one configuration of the invention, the first partial layer having the high doping of the first conductivity type is a silicon layer doped with antimony (Sb). Antimony ions have a low diffusion rate in silicon and are therefore particularly suitable for withstanding later machining and processing steps at relatively high temperature without an impermissibly high degree of diffusion taking place in the process.

The invention and also the method for producing the semiconductor substrate are explained in more detail below on the basis of exemplary embodiments and the associated figures. The figures serve solely for illustrating the invention and have therefore been drawn up only in schematic fashion and not in a manner true to scale. Identical and identically acting parts are designated by identical reference symbols.

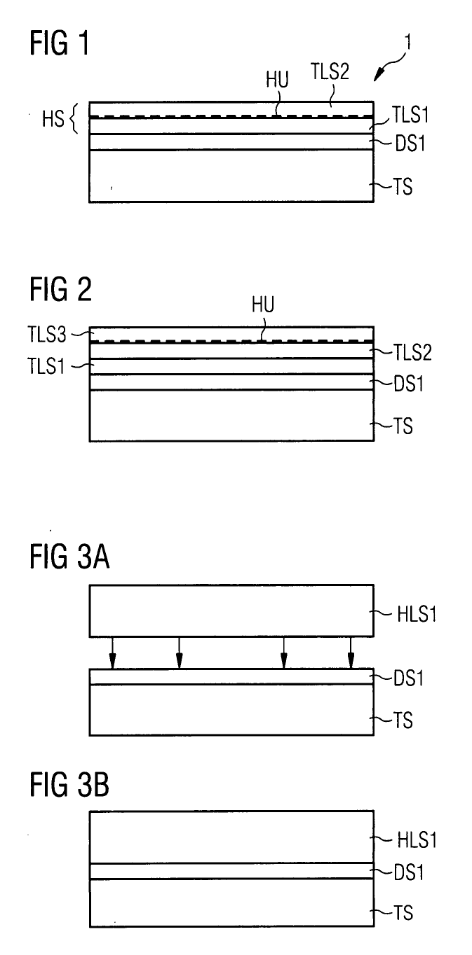

FIG. 1 shows a first exemplary embodiment of a semiconductor substrate with a pn junction,

FIG. 2 shows a semiconductor substrate with three semiconductor partial layers,

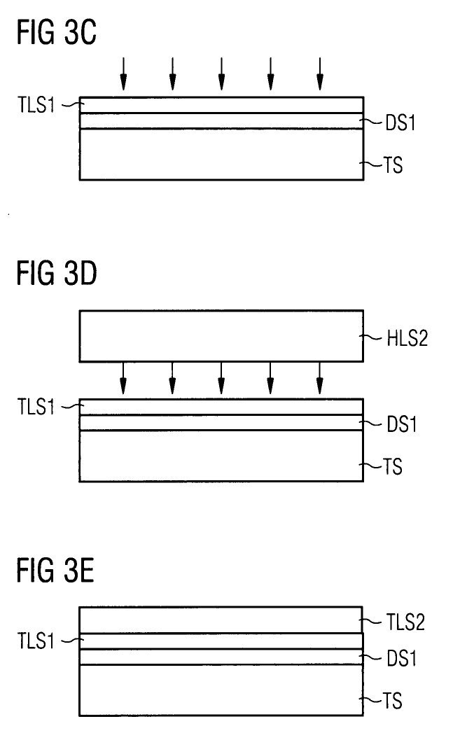

FIG. 3 shows a first exemplary embodiment for producing a semiconductor substrate with a pn junction,

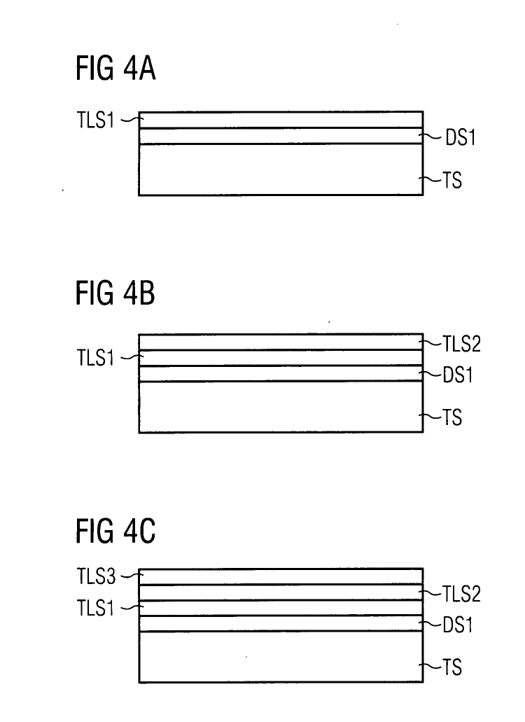

FIG. 4 shows a variant of a production method,

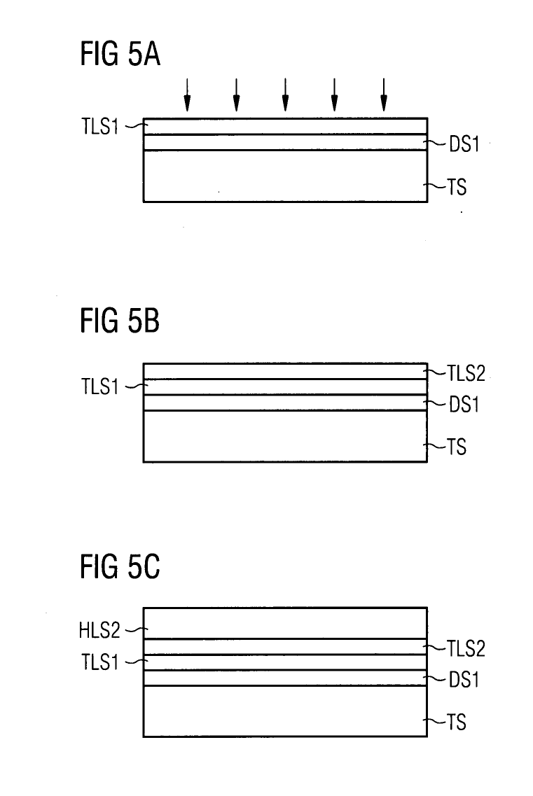

FIG. 5 shows a second variant of the production method,

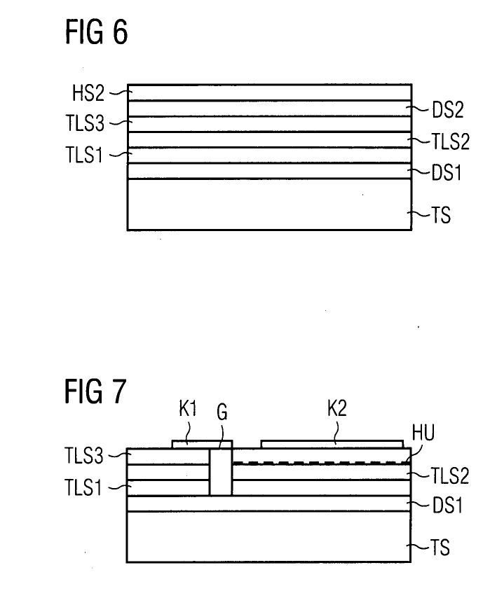

FIG. 6 shows a semiconductor substrate with two semiconductor layer planes,

FIG. 7 shows a semiconductor component realized in the semiconductor substrate.

FIG. 1 shows a first semiconductor substrate according to the invention in schematic cross section. Arranged above a carrier substrate TS is a first dielectric layer DS1, for example an oxide layer on a silicon wafer. Situated above that is a semiconductor layer HS, which is divided into a first partial layer TLS1 and a second partial layer TLS2 arranged above the latter. The first partial layer has a doping of the first conductivity type, and the second partial layer TLS2 has a doping of the second conductivity type. A semiconductor junction HU is thereby formed between the two partial layers.

FIG. 2 shows a second exemplary embodiment of a semiconductor substrate according to the invention, in which the semiconductor layer is formed from three partial layers TLS1 to TLS3. A third partial layer TLS3 having relatively weak doping of the second conductivity type is arranged above a first partial layer TLS1 having relatively high doping of the first type and a second partial layer TLS2 having relatively weak doping of the first conductivity type. A semiconductor junction HU is formed between the second and third partial layers. In this case, the thickness of the first partial layer, which serves only for electrical connection, can be small relative to the thickness of the second and third partial layers, by which the space charge zone is determined.

FIG. 3 shows the production of a semiconductor substrate in accordance with a first method variant on the basis of various method stages in schematic cross section. Proceeding from a carrier substrate TS with a dielectric layer DS1 applied thereto, for example an oxidized silicon wafer, an SOI substrate (silicon-on-isolator) is produced by bonding a first semiconductor substrate HLS1 onto the dielectric layer DS1. The fixed connection between the two substrates is produced with the aid of a wafer bonding method in which the SOI arrangement illustrated in FIG. 3b is obtained. In one variant, the surface of the semiconductor substrate HLS1 may also have an oxide layer, in which case the oxide layer on the surface of the carrier substrate can then optionally also be dispensed with.

The thickness of the semiconductor substrate HLS1 is usually too high for the desired purpose, with the result that said thickness is then thinned in a further step to a desired, freely selectable layer thickness, for example by grinding. Suitable layer thicknesses may lie between 100 Å and 500 μm, depending on the type of component to be realized therein.

FIG. 3c shows the doping of the first partial layer TLS1 obtained after grinding. This can be effected by implanting a dopant of the first conductivity type after grinding. However, it is always also possible to use wafers that have already been produced in correspondingly doped fashion and need no additional doping. A second partial layer is subsequently produced by bonding a second semiconductor substrate HS2 onto the surface of the first partial layer TLS1. The second semiconductor substrate has in its surface a doping of the second conductivity type, which is either concomitantly produced during wafer production or is formed by depositing a doped epitaxial layer on the surface of the second semiconductor substrate HLS2.

The arrangement illustrated in FIG. 3e is obtained after carrying out a wafer bonding method and, if appropriate, thinning the second semiconductor substrate HS2 to the layer thickness desired for the second partial layer TLS2. A semiconductor junction is formed between the first partial layer TLS1 of the first conductivity type and the second partial layer TLS2 of the second conductivity type.

In the method described in FIG. 3 it is possible to vary the thickness of the partial layers independently of one another and to optimize it depending on a desired semiconductor component to be realized,therein. It is thus possible, for example, to provide a first partial layer such that it is relatively thin, whereas the second partial layer is relatively thick. Depending on the type of desired semiconductor component, total layer thicknesses of the semiconductor layer HS of 50 to 200 μm are particularly preferred in this case.

FIG. 4 shows a further method variant for producing a semiconductor substrate according to the invention. This variant starts from an SOI substrate, formed from a carrier substrate TS, a dielectric layer DS1 and a first partial layer TLS1. This SOI substrate can be obtained according to the first exemplary embodiment, as is illustrated for example in FIG. 3c. It is also possible to carry out the first step of the method illustrated in FIG. 3a with a correspondingly doped or with a first semiconductor substrate HLS1 having a doped epitaxial layer, with the result that an SOI substrate with a doped first partial layer TLS1 is obtained. In the next step, a second partial layer TLS2 is applied in an epitaxial method. Preferably, the first partial layer is highly doped, whereas the second partial layer is weakly doped, but both using dopants of the first conductivity type.

In the next step, a third partial layer TLS3 is likewise applied in an epitaxial method, to be precise as a semiconductor layer weakly doped with dopant of the second conductivity type. It is possible, for example, to provide the dopings in the order antimony, arsenic and boron in the partial layers TLS1 to TLS3.

FIG. 5 shows a further exemplary embodiment of how a semiconductor substrate according to the invention can be produced. An SOI substrate as illustrated in FIG. 3c or FIG. 4a is again taken as a starting point. FIG. 5a shows this substrate during a doping step that produces a high doping of the first conductivity type. It goes without saying that all dopings in wafers, semiconductor layers or in partial layers can, of course, also be introduced during the crystal growth and therefore do not require any subsequent doping.

A second partial layer TLS2 having a doping of the first conductivity type, but a lower dopant concentration, is applied above that in an epitaxial process. FIG. 5b shows the arrangement at this stage. A second semiconductor substrate HLS2 is subsequently bonded on above that by means of a wafer bonding method, said second semiconductor substrate having a doping of the second conductivity type at least in a surface region for example in the form of an epitaxial layer. The semiconductor layer of the second semiconductor substrate HLS2 can subsequently be thinned to the desired thickness of the second partial layer TLS2, for example by grinding.

FIG. 6 shows a third exemplary embodiment of a semiconductor substrate according to the invention, in which there is arranged above the semiconductor layer formed from three partial layers TLS1, TLS2 and TLS3 a second dielectric layer DS2 and, above the latter, a second semiconductor layer HS2. This can be obtained by producing a second dielectric layer DS2 by means of oxidizing the third partial layer TLS3 of the first exemplary embodiment and subsequent wafer bonding of a semiconductor substrate and subsequent thinning thereof. In this embodiment, too, the second partial layer is optional and can also be omitted.

FIG. 7 shows a semiconductor substrate according to the invention in schematic cross section, in which a semiconductor component is realized. A semiconductor substrate formed in accordance with FIG. 2, for example, is used. Said semiconductor substrate comprises the three partial layers TLS1, TLS2 and TLS3, wherein a semiconductor junction HU is formed between TLS2 and TLS3 and makes the semiconductor layer with the three partial layers into the diode. In order to make contact with the diode, an electrical contact to the first partial layer TLS1 is required. For this purpose, a trench is etched into the semiconductor layer, for example by means of reactive ion etching, wherein a resist mask or a hard mask can be used. The dielectric layer DS1 can serve as an etching stop layer in this case.

The trench is subsequently filled with an electrically conductive material, for example with doped polysilicon. This produces an electrically conductive contact from the surface to the first partial layer TLS1, which has a high conductivity in the area on account of its high doping of the first conductivity type. It is possible to provide a plurality of such trenches G for the semiconductor component or even to surround the semiconductor component with a single trench of this type in frame-type fashion. The second contact K2 of the diode is arranged on the surface of the third partial layer TLS3, and makes contact with the third partial layer TLS3. A first contact K1 serves for connection of the conductive material in the trench G and thus for the counterelectrode of the diode.

However, the contact K1 can also be used for connecting and hence for interconnecting the semiconductor component IC with the diode.

The invention is not restricted to the exemplary embodiments or the figures. Rather, it is possible to deviate from the specified examples in all details. The semiconductor layers are preferably silicon, but other semiconductor materials can also be used. The thin layers are preferably oxide layers, but other dielectric materials can also be employed. The carrier substrate is preferably likewise a silicon semiconductor wafer, but can also be any other mechanically stable and preferably crystalline material. The thicknesses of the partial layers can be chosen independently of one another. It is also possible to realize a semiconductor layer with more than three partial layers provided that a semiconductor junction is formed between two of the partial layers.

The semiconductor component specified only by way of example in FIG. 7 can be varied as desired, FIG. 7 only specifying very general structures for such a component.

1. A semiconductor substrate with multilayer constructions, comprising:
a carrier substrate;
a dielectric layer; and
a semiconductor layer, in which a pn junction is formed in continuous fashion.

2. The semiconductor substrate as claimed in claim 1, in which the semiconductor layer comprises a monocrystalline SOI layer.

3. The semiconductor substrate as claimed in claim 1, in which the semiconductor layer is weakly doped in the region of the pn junction.

4. The semiconductor substrate as claimed in claim 3, in which the semiconductor layer has a first, relatively thin partial layer having a high doping of a first conductivity type, a second partial layer relatively thicker than said first partial layer and having a weak doping of the first conductivity type, and a third partial layer having weak doping of the second conductivity type.

5. The semiconductor substrate as claimed in claim 1, in which the carrier substrate and the dielectric layer are formed by a silicon wafer with an oxide layer.

6. The semiconductor substrate as claimed in claim 1, in which there is arranged above the semiconductor layer, in which the pn junction is provided, a second dielectric layer and, above the latter, a second monocrystalline semiconductor layer.

7. The semiconductor substrate as claimed in claim 4, in which the first partial layer having the high doping of the first conductivity type is a silicon layer doped with antimony.

8. A method for producing a semiconductor substrate with multilayer construction, comprising the steps of:
arranging an oxide layer and, above the latter, a first doped partial layer of a semiconductor layer on a carrier substrate in wafer form; and
producing at least one further doped partial layer of the semiconductor layer above the first doped partial layer having a doping of an opposite conductivity type to that of the first partial layer, with the result that a semiconductor junction is formed.

9. The method as claimed in claim 8, comprising the steps of:
producing an oxide layer on the surface of at least one element, selected from said carrier substrate and a semiconductor wafer;
connecting said carrier substrate and semiconductor wafer with embedding of the oxide layer by means of a wafer bonding method;
reducing the layer thickness of the semiconductor wafer, a first partial layer being obtained and;
providing a doping of the first conductivity type in the partial layer.

10. The method as claimed in claim 8,
in which the further partial layer is deposited in doped fashion by epitaxy.

11. The method as claimed in claim 8, in which the further partial layer is produced by wafer bonding with a doped second semiconductor wafer and subsequent thinning to the thickness of the further partial layer.

12. The method as claimed in claim 8, in which a second weakly doped or intrinsic partial layer of the semiconductor layer is produced between the first doped partial layer and the further doped partial layer.

13. A semiconductor substrate with multilayer construction, comprising:
a carrier substrate;
a first dielectric layer above said carrier substrate;
a first monocrystalline semiconductor layer, in which a pn junction is formed in continuous fashion, above said first dielectric layer;
a second dielectric layer above said first dielectric layer; and
a second monocrystalline semiconductor layer above said second dielectric layer.

14. A method for producing a semiconductor substrate with multilayer construction, comprising the steps of:
arranging on a carrier substrate in wafer form an oxide layer and, above said oxide layer, a semiconductor layer;
forming the semiconductor layer to comprise a first doped partial layer and at least one further doped partial layer, the doping of which is of an opposite conductivity type to that of the first partial layer; and
wherein at least one of the further doped partial layers of the semiconductor layer is applied by means of a wafer bonding method.
